(19) United States
(12) Patent Application Publication
(10) Pub. No.: US 2022/0406611 A1
(43) Pub. Date: Dec. 22, 2022

(54) METHOD FOR MANUFACTURING SEMICONDUCTOR DEVICE

(71) Applicant: Kioxia Corporation, Tokyo (JP)

(72) Inventors: Atsushi TAKAHASHI, Yokkaichi (JP); Tsubasa IMAMURA, Kuwana (JP); Wu LI, Yokkaichi (JP); Yuto ITAGAKI, Yokkaichi (JP); Minki CHOU, Yokkaichi (JP)

(73) Assignee: Kioxia Corporation, Tokyo (JP)

(21) Appl. No.: 17/643,543

(22) Filed: Dec. 9, 2021

(30) Foreign Application Priority Data
Jun. 16, 2021 (JP) 2021-100233

(51) Int. Cl. H01L 21/3065; H01J 37/32; H01L 21/02

(52) U.S. Cl. CPC H01L 21/30655; H01J 37/32192; H01L 21/02112; H01J 2237/334

(57) ABSTRACT

A method for manufacturing a semiconductor device according to an embodiment is a method for manufacturing a semiconductor device including performing a first etching process of forming a recess in a layer to be processed formed on a substrate by reactive ion etching using a first gas, performing a first process of supplying hydrogen radicals to the recess by using a second gas containing hydrogen in a state where a temperature of the substrate is equal to or more than 200° C. and equal to or less than 350° C. after the first etching process, and performing a second etching process of etching a bottom surface of the recess by reactive ion etching using a third gas after the first process.

### CROSS-REFERENCE TO RELATED APPLICATION

This application is based upon and claims the benefit of priority from Japanese Patent Application No. 2021-100233, filed on Jun. 16, 2021, the entire contents of which are incorporated herein by reference.

### FIELD

Embodiments described herein relate generally to a method for manufacturing a semiconductor device.

### BACKGROUND

Along with scaling-down of a semiconductor device, it is necessary to form a recess having a high aspect ratio in a layer to be processed with high processing accuracy. For example, when a three-dimensional semiconductor memory is manufactured, it is desirable that a shape of a memory hole having a high aspect ratio is prevented from becoming a bowing shape.

### BRIEF DESCRIPTION OF THE DRAWINGS

FIG. 1 is a schematic cross-sectional view of a semiconductor device manufactured by a method for manufacturing a semiconductor device according to a first embodiment;

FIG. 2 is a schematic diagram of an example of a reactive ion etching apparatus used in the method for manufacturing a semiconductor device according to the first embodiment;

FIG. 3 is a schematic diagram of an example of a microwave plasma apparatus used in the method for manufacturing a semiconductor device according to the first embodiment;

FIGS. 4A, 4B, 4C, and 4D are schematic diagrams illustrating the method for manufacturing a semiconductor device according to the first embodiment;

FIGS. 5A, 5B, 5C, and 5D are schematic diagrams illustrating the method for manufacturing a semiconductor device according to the first embodiment;

FIGS. 6A, 6B, 6C, and 6D are schematic diagrams illustrating the method for manufacturing a semiconductor device according to the first embodiment;

FIGS. 7A, 7B, and 7C are schematic diagrams illustrating the method for manufacturing a semiconductor device according to the first embodiment;

FIGS. 8A, 8B, and 8C are explanatory diagrams of functions of a method for manufacturing a semiconductor device according to a second embodiment; and

FIG. 9 is a schematic diagram of an example of a reactive ion etching apparatus used in a method for manufacturing a semiconductor device according to a third embodiment.

### DETAILED DESCRIPTION

A method for manufacturing a semiconductor device according to an embodiment includes performing a first etching process forming a recess in a layer to be processed formed on a substrate, the recess formed by reactive ion etching using a first gas; performing a first process after the first etching process, the first process supplying hydrogen radicals to the recess by using a second gas containing hydrogen in a state where a temperature of the substrate is equal to or more than 200° C. and equal to or less than 350° C.; and performing a second etching process after the first process, the second etching process etching a bottom surface of the recess by reactive ion etching using a third gas.

Hereinafter, embodiments of the present disclosure will be described with reference to the drawings. In the following description, the same or similar members or the like will be denoted by the same reference numerals, and the description of the members once described or the like may be appropriately omitted.

In the present specification, the term “upper” or “lower” may be used for the sake of convenience. The term “upper” or “lower” is, for example, a term indicating a relative positional relationship in the drawings. The term “upper” or “lower” is not a term that necessarily defines a positional relationship with respect to gravity.

Qualitative analysis and quantitative analysis of a chemical composition of members constituting a semiconductor device in the present specification can be performed by, for example, secondary ion mass spectrometry (SIMS) or energy dispersive X-ray spectroscopy (EDX). For example, a transmission electron microscope (TEM) or a scanning electron microscope (SEM) can be used for measuring a thickness of the members constituting the semiconductor device, a distance between the members, and the like.

Hereinafter, a method for manufacturing a semiconductor device according to an embodiment will be described with reference to the drawings.

### First Embodiment

A method for manufacturing a semiconductor device according to a first embodiment includes performing a first etching process of forming a recess in a layer to be processed formed on a substrate by reactive ion etching using a first gas, performing a first process of supplying hydrogen radicals to the recess by using a second gas containing hydrogen in a state where a temperature of the substrate is equal to or more than 200° C. and equal to or less than 350° C. after the first etching process, and performing a second etching process of etching a bottom surface of the recess by reactive ion etching using a third gas after the first process.

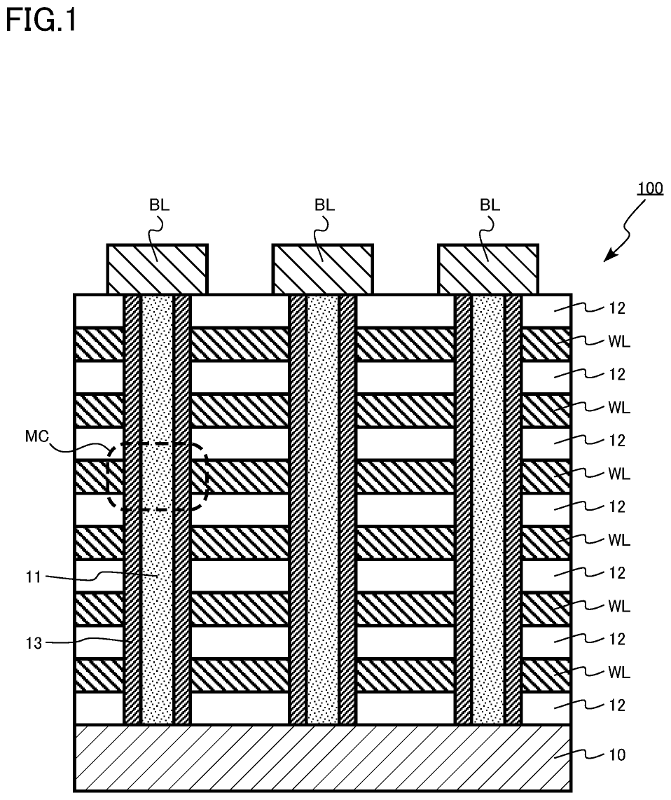

FIG. 1 is a schematic cross-sectional view of a semiconductor device manufactured by the method for manufacturing a semiconductor device according to the first embodiment. The semiconductor device manufactured by the method for manufacturing a semiconductor device according to the first embodiment is a nonvolatile memory 100 in which memory cells are three-dimensionally disposed. FIG. 1 is a cross-sectional view of a memory cell array of the nonvolatile memory 100.

The nonvolatile memory 100 includes a silicon substrate 10, a channel layer 11, a plurality of interlayer insulating layers 12, a gate insulating layer 13, a plurality of word lines WL, and a plurality of bit lines BL. The nonvolatile memory 100 includes a plurality of memory cells MC disposed three-dimensionally. A region surrounded by a dotted line in FIG. 1 corresponds to one memory cell MC.

The channel layer 11 extends in a normal direction of a surface of the silicon substrate 10. The channel layer 11 is electrically connected to the silicon substrate 10. The channel layer 11 functions as a channel region of a transistor of the memory cell MC. The channel layer 11 is a semiconductor. The channel layer 11 is, for example, polycrystalline silicon.

The word lines WL are stacked in the normal direction of the surface of the silicon substrate 10. The word line WL functions as a gate electrode of the transistor of the memory cell MC. The word line WL is, for example, a plate-like conductor. The word line WL is, for example, tungsten (W). The channel layer 11 penetrates the plurality of word lines WL.

The interlayer insulating layer 12 is provided between the word line WL and the word line WL. The interlayer insulating layer 12 electrically isolates the word line WL from the word line WL.

The bit line BL extends in a direction parallel to the surface of the silicon substrate 10. The bit line BL is electrically connected to the channel layer 11.

The gate insulating layer 13 is provided between the channel layer 11 and the word line WL. The gate insulating layer 13 includes, for example, a tunnel insulating film, a charge storage film, and a block insulating film (all not illustrated). The tunnel insulating film is, for example, a silicon oxide film. The charge storage film is, for example, a silicon nitride film. The block insulating film is, for example, an aluminum oxide film.

The memory cell MC stores data by charges stored in the charge storage film of the gate insulating layer 13. A threshold voltage of the transistor of the memory cell MC changes depending on the amount of charges stored in the charge storage film. The data stored in the memory cell MC is read by monitoring a current flowing between the word line WL and the bit line BL, which changes depending on the threshold voltage of the transistor.

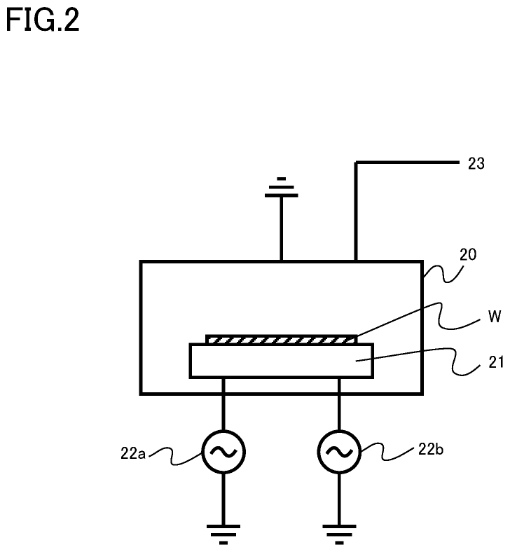

FIG. 2 is a schematic diagram of an example of a reactive ion etching apparatus used in the method for manufacturing a semiconductor device according to the first embodiment. The reactive ion etching apparatus (RIE apparatus) of FIG. 2 is a two-frequency capacitively coupled plasma apparatus (CCP apparatus). The RIE apparatus of FIG. 2 generates plasma by using a capacitively coupled plasma method.

The RIE apparatus includes, for example, a chamber 20, a holder 21, a first high-frequency power supply 22a, a second high-frequency power supply 22b, and a gas supply port 23. The chamber 20 is an example of a first chamber.

The holder 21 is provided in the chamber 20. The holder 21 mounts a semiconductor substrate W, for example. The holder 21 has, for example, an electrostatic chuck on an upper portion.

The first high-frequency power supply 22a has a function of applying a high-frequency power to the chamber 20. Plasma is generated in the chamber 20 by the first high-frequency power supply 22a. The high-frequency power to be applied by the first high-frequency power supply 22a is, for example, equal to or more than 50 W and equal to or less than 10,000 W. A frequency to be applied by the first high-frequency power supply 22a is, for example, equal to or more than 20 MHz and equal to or less than 200 MHz.

The second high-frequency power supply 22b has a function of applying a high-frequency power to the holder 21. Energy of ions colliding with the semiconductor substrate W is controlled by applying the high-frequency power to the holder 21. The high-frequency power to be applied to the holder 21 is, for example, equal to or more than 100 W and equal to or less than 30,000 W. A frequency applied to the holder 21 is lower than the frequency applied to the chamber 20 by the first high-frequency power supply 22a. The frequency applied to the holder 21 is, for example, equal to or more than 0.1 MHz and equal to or less than 10 MHz.

An etching gas is supplied from the gas supply port 23 to the chamber 20. The semiconductor substrate W is anisotropically etched by using the etching gas. The semiconductor substrate W is anisotropically etched in the chamber 20 by the high-frequency power by using the plasma generated from the etching gas.

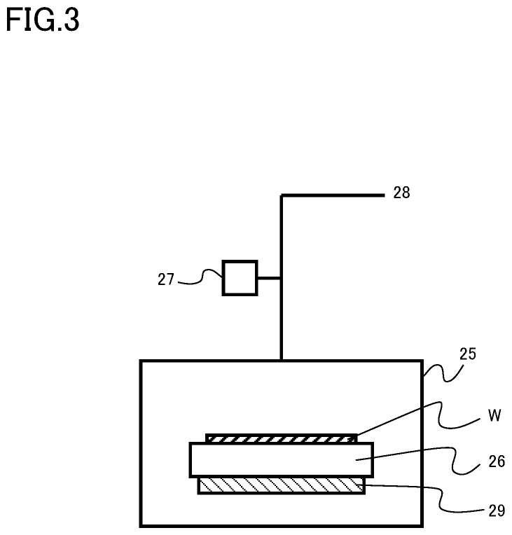

FIG. 3 is a schematic diagram of an example of a microwave plasma apparatus used in the method for manufacturing a semiconductor device according to the first embodiment. The microwave plasma apparatus of FIG. 3 generates plasma by using a microwave plasma method.

The microwave plasma apparatus includes, for example, a chamber 25, a holder 26, a microwave generation mechanism 27, a gas supply port 28, and a heater 29. The chamber 25 is an example of a second chamber.

A gas supplied from the gas supply port 28 is irradiated with microwaves generated by the microwave generation mechanism 27, and plasma is generated. The plasma introduced into the chamber 25 becomes a downflow and is supplied to a surface of the semiconductor substrate W.

The heater 29 heats the holder 26. The semiconductor substrate W is heated by heating the holder 26. A surface treatment of the semiconductor substrate W is performed by the plasma supplied to the heated surface of the semiconductor substrate W.

A high-frequency power is not applied to holder 26 of the microwave plasma apparatus.

Next, an example of the method for manufacturing a semiconductor device according to the first embodiment will be described.

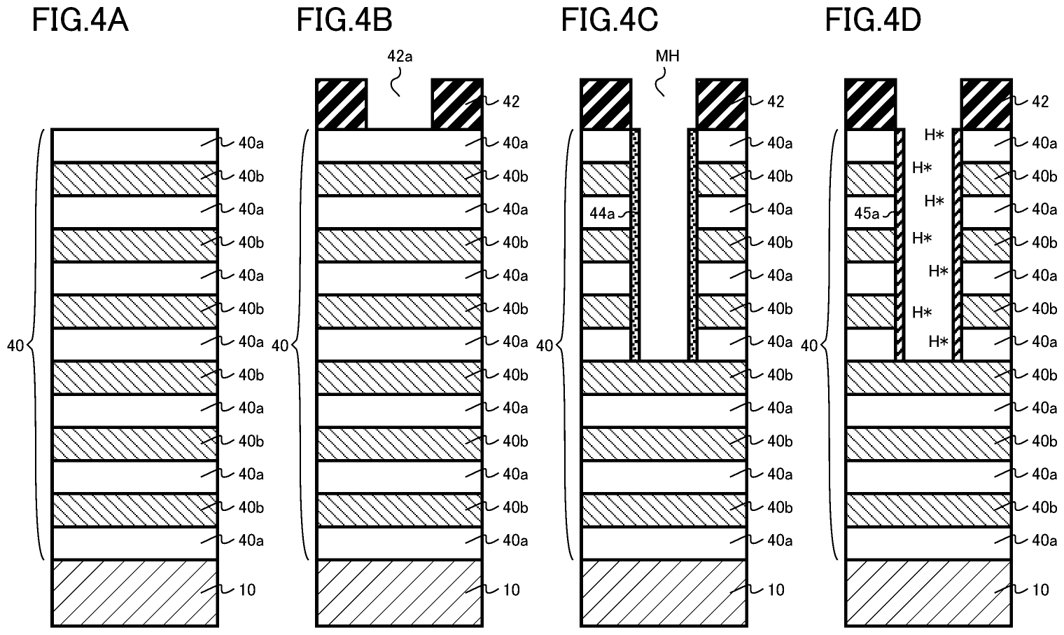

FIGS. 4A, 4B, 4C, 4D, 5A, 5B, 5C, 5D, 6A, 6B, 6C, 6D, 7A, 7B, and 7C are schematic diagrams illustrating the method for manufacturing a semiconductor device according to the first embodiment. FIGS. 4A, 4B, 4C, 4D, 5A, 5B, 5C, 5D, 6A, 6B, 6C, 6D, 7A, 7B, and 7C correspond to portions including one channel layer 11 of FIG. 1.

First, a stacked body 40 is formed on the silicon substrate 10 (FIG. 4A). The silicon substrate 10 is an example of a substrate. The stacked body 40 is an insulating layer. The stacked body 40 is an example of a layer to be processed.

The stacked body 40 has a structure in which silicon oxide layers 40a and silicon nitride layers 40b are alternately stacked. The silicon oxide layer 40a is an example of a first layer. The silicon oxide layer 40a contains silicon (Si) and oxygen (O). The silicon nitride layer 40b is an example of a second layer. The silicon nitride layer 40b contains silicon (Si) and nitrogen (N). The silicon oxide layers 40a and the silicon nitride layers 40b are formed by, for example, a chemical vapor deposition method (CVD method).

A part of the silicon oxide layer 40a finally becomes the interlayer insulating layer 12.

Subsequently, a mask layer 42 having a hole pattern 42a is formed on the stacked body 40 (FIG. 4B). The mask layer 42 contains, for example, carbon (C). The mask layer is, for example, a carbon layer.

The mask layer 42 is formed by, for example, a sputtering method. The hole pattern 42a is formed by using, for example, a lithography method and a RIE method.

For example, a resist layer, an insulating layer, or a metal layer can also be used as the mask layer 42.

Subsequently, the silicon substrate 10 is loaded into the chamber 20 of the RIE apparatus illustrated in FIG. 2. The loaded silicon substrate 10 is mounted on the holder 21.

In the chamber 20 of the RIE apparatus, a first etching process is performed by using the mask layer 42 as a mask. A memory hole MH is formed on a surface of the stacked body 40 by the first etching process (FIG. 4C). The memory hole MH is an example of a recess.

During the first etching process, the memory hole MH does not penetrate the stacked body 40. During the first etching process, the etching is stopped in the middle of the stacked body 40.

During the first etching process, for example, a first etching gas is supplied from the gas supply port 23 into the chamber 20. The first etching process is performed by using the first etching gas. The first etching gas is an example of a first gas. The first etching gas is, for example, a gas containing carbon (C) and fluorine (F).

A temperature of the silicon substrate 10 during the first etching process is, for example, equal to or less than 20° C. The first etching process is performed on the silicon substrate 10 in a state of, for example, 20° C. or lower. The silicon substrate 10 is cooled, for example, by heat dissipation to the holder 21. The holder 21 is cooled by using, for example, a refrigerant flowing through a flow path (not illustrated in FIG. 2).

During the first etching process, a first protective film 44a is formed on a surface of the memory hole MH. The first protective film 44a is formed, for example, on a sidewall of the memory hole MH. The first protective film 44a is formed simultaneously with the formation of the memory hole MH. The first protective film 44a is an example of a first film.

The first protective film 44a is a reaction product derived from the first etching gas. The first protective film 44a contains, for example, carbon (C) and fluorine (F). The first protective film 44a is, for example, a fluorocarbon film.

After the first etching process, the silicon substrate 10 is unloaded from the chamber 20 of the RIE apparatus. Subsequently, the silicon substrate 10 is loaded into the microwave plasma apparatus illustrated in FIG. 3. The loaded silicon substrate 10 is mounted on the holder 26.

In the chamber 25 of the microwave plasma apparatus, a first modifying process for supplying hydrogen radicals to the memory hole MH is performed (FIG. 4D). The first modifying process is an example of a first process.

During the first modifying process, a first modifying gas is supplied from the gas supply port 28. The first modifying gas is a gas containing hydrogen (H). The first modifying gas contains, for example, a hydrogen gas. The first modifying gas is an example of a second gas.

During the first modifying process, the modifying gas supplied from the gas supply port 28 is irradiated with microwaves generated by the microwave generation mechanism, and plasma containing hydrogen radicals is generated.

The plasma containing hydrogen radicals is introduced into the chamber 25. The plasma containing hydrogen radicals introduced into the chamber 25 becomes a downflow and is supplied to the surface of the silicon substrate 10.

The hydrogen radicals are supplied into the memory hole MH. A surface of the first protective film 44a is exposed to the hydrogen radicals.

The first modifying process is performed in a state where the temperature of the silicon substrate 10 is equal to or more than 200° C. and equal to or less than 350° C. The silicon substrate 10 is heated by the holder 26 heated by the heater 29. The temperature of the silicon substrate 10 during the first modifying process is higher than, for example, the temperature of the silicon substrate 10 during the first etching process.

The temperature of the silicon substrate 10 is measured by, for example, a thermometer not illustrated in FIG. 3. The thermometer is, for example, a radiation thermometer or a thermocouple thermometer.

During the first modifying process, for example, a high-frequency power is not applied to the holder 26 of the microwave plasma apparatus. The high-frequency power to be applied to the silicon substrate 10 during the first modifying process is lower than the high-frequency power to be applied to the silicon substrate 10 during the first etching process.

During the first modifying process, the first protective film 44a is modified to a first modified protective film 45a. A chemical composition of the first modified protective film 45a is different from a chemical composition of the first protective film 44a, for example.

During the first modifying process, the first protective film 44a is reduced, for example. During the first modifying process, for example, a fluorine concentration of the first protective film 44a decreases.

During the first modifying process, for example, a film is not formed on the first protective film 44a. After the first modifying process, for example, an inner diameter of the memory hole MH does not decrease. After the first modifying process, for example, a volume of a cavity of the memory hole MH does not decrease.

After the first modifying process, the silicon substrate 10 is unloaded from the chamber 25 of the microwave plasma apparatus. Subsequently, the silicon substrate 10 is loaded into the RIE apparatus. The loaded silicon substrate 10 is mounted on the holder 21.

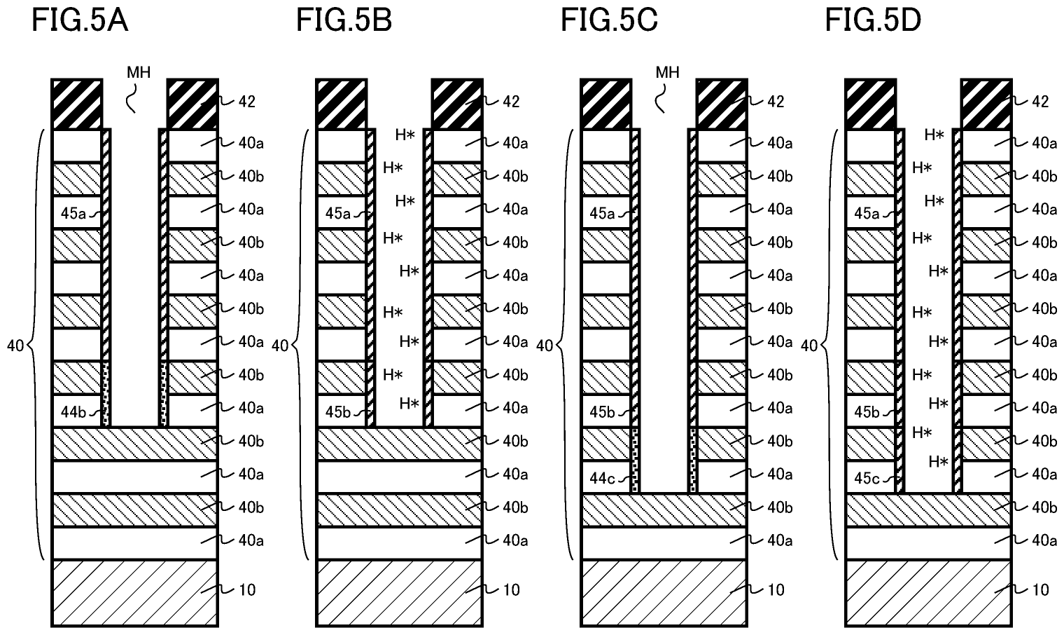

In the chamber 20 of the RIE apparatus, a second etching process is performed by using the mask layer 42 as a mask. At least a bottom surface of the memory hole MH is etched by the second etching process (FIG. 5A).

After the second etching process, the memory hole MH becomes deeper than immediately after the first etching process. In the second etching process, the memory hole MH does not penetrate the stacked body 40. In the second etching process, the etching is stopped in the middle of the stacked body 40.

During the second etching process, for example, a second etching gas is supplied from the gas supply port 23 into the chamber 20. The second etching process is performed by using the second etching gas. The second etching gas is an example of a third gas.

The second etching gas is, for example, a gas containing carbon (C) and fluorine (F). The second etching gas is, for example, the same type of gas as the first etching gas.

The second etching process is performed, for example, in the same chamber 20 as the first etching process under the same conditions.

During the second etching process, a second protective film 44b is formed on the surface of the memory hole MH. The second protective film 44b is formed, for example, on the sidewall of the memory hole MH at a portion deepened by the second etching process. The second protective film 44b is an example of a second film.

The second protective film 44b is a reaction product derived from the second etching gas. The second protective film 44b contains, for example, carbon (C) and fluorine (F). The second protective film 44b is, for example, a fluorocarbon film.

After the second etching process, the silicon substrate 10 is unloaded from the chamber 20 of the RIE apparatus. Subsequently, the silicon substrate 10 is loaded into the microwave plasma apparatus.

In the chamber 25 of the microwave plasma apparatus, a second modifying process of supplying hydrogen radicals to the memory hole MH is performed (FIG. 5B). The second modifying process is an example of a second process.

During the second modifying process, a second modifying gas is supplied from the gas supply port 28. The second modifying gas is a gas containing hydrogen (H). The second modifying gas includes, for example, a hydrogen gas. The second modifying gas is an example of a fourth gas.

The second modifying process is performed, for example, in the same chamber 25 as the first modifying process under the same conditions.

During the second modifying process, the second protective film 44b is modified to a second modified protective film 45b. A chemical composition of the second modified protective film 45b is different from a chemical composition of the second protective film 44b, for example.

During the second modifying process, the second protective film 44b is reduced, for example. During the second modifying process, for example, a fluorine concentration of the second protective film 44b decreases.

After the second modifying process, the silicon substrate 10 is unloaded from the chamber 25 of the microwave plasma apparatus. Subsequently, the silicon substrate 10 is loaded into the RIE apparatus. The loaded silicon substrate 10 is mounted on the holder 21.

In the chamber 20 of the RIE apparatus, a third etching process is performed by using the mask layer 42 as a mask. At least the bottom surface of the memory hole MH is etched by the third etching process (FIG. 5C).

After the third etching process, the memory hole MH becomes deeper than immediately after the second etching process. During the third etching process, the memory hole MH does not penetrate the stacked body 40. During the third etching process, the etching is stopped in the middle of the stacked body 40.

During the third etching process, for example, a third etching gas is supplied from the gas supply port 23 into the chamber 20. The third etching process is performed by using the third etching gas. The third etching gas is an example of a fifth gas.

The third etching gas is, for example, a gas containing carbon (C) and fluorine (F). The third etching gas is, for example, the same type of gas as the first etching gas and the second etching gas.

The third etching process is performed under the same conditions as the first etching process and the second etching process, for example.

During the third etching process, a third protective film 44c is formed on the surface of the memory hole MH. The third protective film 44c is formed, for example, on the sidewall of the memory hole MH at a portion deepened by the third etching process.

The third protective film 44c is a reaction product derived from the third etching gas. The third protective film 44c contains, for example, carbon (C) and fluorine (F). The third protective film 44c is, for example, a fluorocarbon film.

After the third etching process, the silicon substrate 10 is unloaded from the chamber 20 of the RIE apparatus. Subsequently, the silicon substrate 10 is loaded into the microwave plasma apparatus.

In the chamber 25 of the microwave plasma apparatus, a third modifying process of supplying hydrogen radicals to the memory hole MH is performed (FIG. 5D).

During the third modifying process, a third modifying gas is supplied from the gas supply port 28. The third modifying gas is a gas containing hydrogen (H). The third modifying gas includes, for example, a hydrogen gas.

The third modifying process is performed, for example, in the same chamber 25 as the first modifying process and the second modifying process under the same conditions.

During the third modifying process, the third protective film 44c is modified to a third modified protective film 45c. A chemical composition of the third modified protective film 45c is different from a chemical composition of the third protective film 44c, for example.

During the third modifying process, the third protective film 44c is reduced, for example. During the third modifying process, for example, a fluorine concentration of the third protective film 44c decreases.

After the third modifying process, the silicon substrate 10 is unloaded from the chamber 25 of the microwave plasma apparatus. Subsequently, the silicon substrate 10 is loaded into the RIE apparatus. The loaded silicon substrate 10 is mounted on the holder 21.

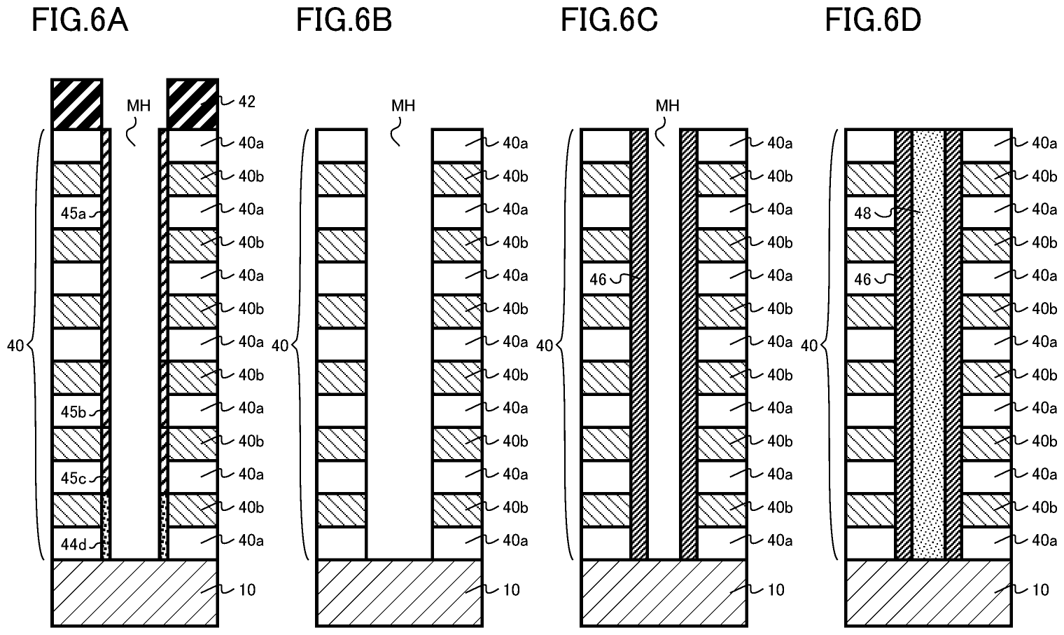

In the chamber 20 of the RIE apparatus, a fourth etching process is performed by using the mask layer 42 as a mask. At least the bottom surface of the memory hole MH is etched by the fourth etching process (FIG. 6A).

After the fourth etching process, the memory hole MH becomes deeper than immediately after the third etching process. During the fourth etching process, the memory hole MH penetrates the stacked body 40. The memory hole MH reaches the silicon substrate 10.

During the fourth etching process, for example, a fourth etching gas is supplied from the gas supply port 23 into the chamber 20. The fourth etching process is performed by using the fourth etching gas.

The fourth etching gas is, for example, a gas containing carbon (C) and fluorine (F). The fourth etching gas is, for example, the same type of gas as the first etching gas, the second etching gas, and the third etching gas.

The fourth etching process is performed under the same conditions as the first etching process, the second etching process, and the third etching process, for example.

During the fourth etching process, a fourth protective film 44d is formed on the surface of the memory hole MH. The fourth protective film 44d is formed, for example, on the sidewall of the memory hole MH at a portion deepened by the fourth etching process.

The fourth protective film 44d is a reaction product derived from the fourth etching gas. The fourth protective film 44d contains, for example, carbon (C) and fluorine (F). The fourth protective film 44d is, for example, a fluorocarbon film.

An aspect ratio of the memory hole MH penetrating the stacked body 40 is, for example, equal to or more than 30.

After the fourth etching process, the silicon substrate 10 is unloaded from the chamber 20 of the RIE apparatus.

The first etching gas, the second etching gas, the third etching gas, and the fourth etching gas contain, for example, carbon (C) and fluorine (F). The first etching gas, the second etching gas, the third etching gas, and the fourth etching gas contain, for example, oxygen (O). The first etching gas, the second etching gas, the third etching gas, and the fourth etching gas contain, for example, hydrogen (H).

The first etching gas, the second etching gas, the third etching gas, and the fourth etching gas contain, for example, CxHyFz (x is an integer of 1 or more, y is an integer of 0 or more, and z is an integer of 1 or more). The first etching gas, the second etching gas, the third etching gas, and the fourth etching gas contain, for example, C₄F₆, C₄F₈, and CH₂F₂.

The first etching gas, the second etching gas, the third etching gas, and the fourth etching gas contain, for example, an oxygen gas.

The first etching gas, the second etching gas, the third etching gas, and the fourth etching gas are, for example, mixed gases of C₄F₆, C₄F₈, CH₂F₂, and an oxygen gas.

The first etching gas, the second etching gas, the third etching gas, and the fourth etching gas are, for example, the same gas. For example, at least one of the first etching gas, the second etching gas, the third etching gas, and the fourth etching gas is different from the other gases.

The first modifying gas, the second modifying gas, and the third modifying gas contain hydrogen (H). The first modifying gas, the second modifying gas, and the third modifying gas include, for example, a hydrogen gas.

The first modifying gas, the second modifying gas, and the third modifying gas contain, for example, a hydrogen gas and a nitrogen gas. For example, a volume ratio of the hydrogen gas in the first modifying gas, the second modifying gas, and the third modifying gas is equal to or less than 10%, and a volume ratio of the nitrogen gas is equal to or more than 80%. The volume ratio of the hydrogen gas in the first modifying gas, the second modifying gas, and the third modifying gas is, for example, 5%, and the volume ratio of the nitrogen gas is, for example, 95%. The first modifying gas, the second modifying gas, and the third modifying gas are, for example, forming gases.

The first modifying gas, the second modifying gas, and the third modifying gas contain, for example, a hydrogen gas and an argon gas.

The first modifying gas, the second modifying gas, and the third modifying gas contain, for example, a hydrocarbon gas, an ammonia gas, a silane gas, steam, or a hydrogen sulfide gas.

Subsequently, the mask layer 42, the first modified protective film 45a, the second modified protective film 45b, the third modified protective film 45c, and the fourth protective film 44d are removed (FIG. 6B). The mask layer 42, the first modified protective film 45a, the second modified protective film 45b, the third modified protective film 45c, and the fourth protective film 44d are removed by an asking process using oxygen plasma, for example.

Subsequently, a stacked insulating layer 46 is formed in the memory hole MH (FIG. 6C). The stacked insulating layer 46 has, for example, a stacked structure of a silicon oxide film, a silicon nitride film, and an aluminum oxide film. The stacked insulating layer 46 finally becomes the gate insulating layer 13.

Subsequently, a polycrystalline silicon layer 48 is formed in the memory hole MH (FIG. 6D). The polycrystalline silicon layer 48 finally becomes the channel layer 11.

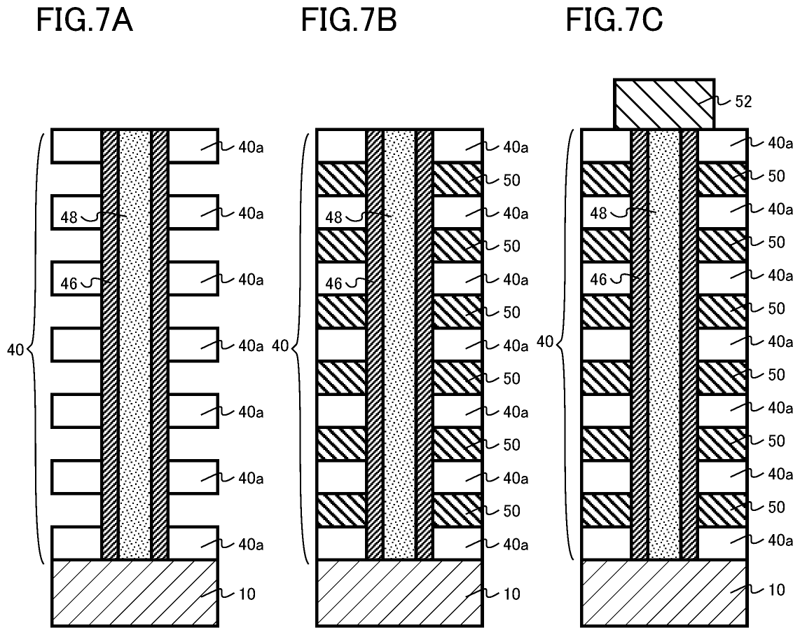

Subsequently, the silicon nitride layer 40b is selectively removed (FIG. 7A).

Subsequently, a first tungsten layer 50 is formed in a region from which the silicon nitride layer 40b has been removed (FIG. 7B). The first tungsten layer 50 finally becomes the word line WL.

Subsequently, a second tungsten layer 52 is formed on the polycrystalline silicon layer 48 (FIG. 7C). The second tungsten layer 52 finally becomes the bit line BL.

The nonvolatile memory 100 illustrated in FIG. 1 is manufactured by the above manufacturing method.

Next, functions and effects of the method for manufacturing a semiconductor device according to the first embodiment will be described.

Hereinafter, for the sake of convenience in description, the first etching process, the second etching process, the third etching process, and the fourth etching process may be collectively referred to simply as an etching process. The first modifying process, the second modifying process, and the third modifying process may be collectively referred to simply as a modifying process. The first protective film 44a, the second protective film 44b, and the third protective film 44c may be collectively referred to simply as a protective film 44. The first modified protective film 45a, the second modified protective film 45b, and the third modified protective film 45c may be collectively referred to simply as a modified protective film 45.

In the nonvolatile memory in which the memory cells are three-dimensionally disposed, for example, a hole diameter of the memory hole is decreased and the number of stacked word lines WL is increased in order to increase a capacity of the memory. When the hole diameter of the memory hole is decreased and the number of stacked word lines WL is increased, it is necessary to form the memory hole having a high aspect ratio (a depth of the memory hole divided by the hole diameter of the memory hole).

When the aspect ratio of the memory hole increases, there is a problem that the memory hole has a bowing shape. The bowing shape of the memory hole is caused by an increase in the hole diameter during etching for forming the memory hole.

During the etching of the memory hole, substances derived from plasmised etching gas adhere to the sidewall, and a protective film is formed on the sidewall. The etching of the sidewall is suppressed by forming the protective film on the sidewall of the memory hole, and the increase in the hole diameter is suppressed.

As a cause of the increase in the hole diameter during the etching of the memory hole, it is considered that the protective film formed on the sidewall of the memory hole during the etching reacts with a material exposed on the sidewall of the memory hole and the etching of the sidewall of the memory hole progresses. The reaction between the protective film and the material exposed on the sidewall progresses, for example, by kinetic energy of ions incident on the protective film during the etching. As the etching of the sidewall of the memory hole progresses, the hole diameter of the memory hole increases.

The sidewall of the memory hole is made of a material containing silicon (Si), such as silicon oxide or silicon nitride. The protective film formed on the sidewall of the memory hole is, for example, a fluorocarbon film containing carbon and fluorine.

For example, the silicon contained in the material forming the sidewall reacts with the fluorine contained in the protective film to form silicon fluoride. When the silicon fluoride is formed and is separated as a gas, the etching of the sidewall of the memory hole progresses. As the etching of the sidewall of the memory hole progresses, the hole diameter of the memory hole increases.

In the method for manufacturing a semiconductor device according to the first embodiment, the protective film 44 formed on the sidewall is modified to form the modified protective film 45 during the etching of the memory hole MH. The reaction between the modified protective film 45 and the material forming the sidewall of the memory hole MH is suppressed by modifying the protective film 44 to the modified protective film 45.

Specifically, for example, the protective film 44 is reduced to form the modified protective film 45. Specifically, for example, the fluorine concentration of the protective film 44 decreases to form the modified protective film 45.

Specifically, for example, the hydrogen radicals are supplied to the surface of the protective film 44 to react the hydrogen radicals with the fluorine in the protective film 44, and thus, hydrogen fluoride is generated. The generated hydrogen fluoride is separated as a gas, and the modified protective film 45 having the fluorine concentration lower than the fluorine concentration of the protective film 44 is formed.

Since the fluorine concentration of the modified protective film 45 decreases, the reaction between the modified protective film 45 and the material forming the sidewall of the memory hole MH is suppressed. Accordingly, the etching of the sidewall of the memory hole MH is suppressed, and the increase in the hole diameter of the memory hole MH is suppressed.

The fluorine concentration of the modified protective film 45 decreases, and thus, a ratio of a carbon-carbon bond (C—C bond) having higher bond energy than bond energy of a carbon-fluorine bond (C—F bond) increases in the modified protective film 45. Accordingly, etching resistance of the protective film during the forming of the memory hole MH also increases.

Thus, in accordance with the method for manufacturing a semiconductor device according to the first embodiment, the etching of the sidewall of the memory hole MH is suppressed, and the shape of the memory hole can be prevented from becoming the bowing shape.

When the protective film 44 is modified by the modifying process, it may be difficult to modify the protective film 44 at a bottom of a deep trench having a large aspect ratio. When the modification of the protective film 44 at the bottom of the trench is insufficient, a shape of the bottom of the trench becomes a bowing shape.

In the method for manufacturing a semiconductor device according to the first embodiment, the hydrogen radicals are used when the modifying process is performed. The hydrogen radicals are hardly deactivated than, for example, hydrogen ions. Thus, it is considered that the hydrogen radicals easily reach the bottom of the deep trench having the large aspect ratio without being deactivated.

In order to modify the protective film 44 by using the hydrogen radicals, it is necessary to apply energy for reacting the hydrogen radicals with fluorine in the protective film 44. In the method for manufacturing a semiconductor device according to the first embodiment, the temperature of the silicon substrate 10 increases. In the method for manufacturing a semiconductor device according to the first embodiment, thermal energy is used as the energy for reacting the hydrogen radicals with the fluorine in the protective film 44.

As a result of examination by the inventors, it has become clear that a temperature of 200° C. or higher is required in order to extract fluorine from the fluorocarbon film by reacting the hydrogen radicals with the fluorine in the fluorocarbon film. It has become clear that the etching of the silicon oxide film progresses by reacting the fluorocarbon film in contact with the silicon oxide film at a temperature exceeding 350° C. It has become clear that decomposition of the fluorocarbon film became apparent at a temperature higher than 300° C.

In the method for manufacturing a semiconductor device according to the first embodiment, the temperature of the silicon substrate 10 on which the stacked body 40 is formed is controlled to 200° C. or higher. Accordingly, the reaction between the hydrogen radicals and the fluorine in the protective film 44 progresses, and the protective film 44 can be modified.

In the method for manufacturing a semiconductor device according to the first embodiment, the temperature of the silicon substrate 10 on which the stacked body 40 is formed is controlled to 350° C. or lower. Accordingly, the reaction between the material of the sidewall of the memory hole MH and the protective film 44 is suppressed, and the etching of the material of the sidewall is suppressed. Thus, the increase in the hole diameter of the memory hole MH is suppressed, and the shape of the memory hole MH can be prevented from becoming the bowing shape.

From the viewpoint of promoting the modification of the protective film 44, the temperature of the silicon substrate 10 during the modifying process is preferably equal to or more than 225° C., and more preferably equal to or more than 250° C. From the viewpoint of suppressing the etching of the material of the sidewall and suppressing the decomposition of the protective film 44, the temperature of the silicon substrate 10 during the modifying process is preferably equal to or less than 325° C. The temperature is more preferably equal to or less than 300° C.

In the method for manufacturing a semiconductor device according to the first embodiment, it is preferable that the temperature of the silicon substrate 10 on which the stacked body 40 is formed is low from the viewpoint of improving an etching speed of the stacked body 40 and improving a throughput of the etching process. In the method for manufacturing a semiconductor device according to the first embodiment, the temperature of the silicon substrate 10 during the etching process is, for example, preferably equal to or less than 20° C., and more preferably equal to or less than 0° C. It is preferable that the temperature of the silicon substrate 10 during the modifying process is higher than the temperature of the silicon substrate 10 during the etching process.

In the method for manufacturing a semiconductor device according to the first embodiment, it is preferable that the high-frequency power to be applied to the silicon substrate 10 during the modifying process is lower than the high-frequency power to be applied to the silicon substrate 10 during the etching process from the viewpoint of suppressing the etching of the mask layer 42 due to the collision of the ions in the plasma with the mask layer 42 during the modifying process. It is more preferable that the high-frequency power is not applied to the silicon substrate 10 during the modifying process.

In the method for manufacturing a semiconductor device according to the first embodiment, it is preferable that the kinetic energy of the ions in the plasma is low from the viewpoint of suppressing the etching of the mask layer 42 due to the collision of the ions in the plasma with the mask layer 42 during the modifying process. Accordingly, it is preferable that the plasma containing the hydrogen radicals used for the modifying process is generated from the first to third modifying gases by using an inductively coupled plasma method, a microwave plasma method, an electron cyclotron resonance method, a helicon wave method, or a hot filament method. The plasma is generated by using the above method, and thus, for example, the kinetic energy of the ions in the plasma can further decrease than the kinetic energy when the plasma is generated by using the capacitively coupled plasma method.

In the method for manufacturing a semiconductor device according to the first embodiment, it is preferable that the hydrogen radicals used for the modifying process are generated by using the hot filament method from the viewpoint of suppressing the etching of the mask layer 42 due to the collision of the ions with the mask layer 42 during the modifying process.

In the method for manufacturing a semiconductor device according to the first embodiment, it is preferable that the first modifying gas, the second modifying gas, and the third modifying gas contain the hydrogen gas and the nitrogen gas, the volume ratio of the hydrogen gas in the first modifying gas, the second modifying gas, and the third modifying gas is equal to or less than 10%, and the volume ratio of the nitrogen gas is equal to or more than 80%. By using the gases, it is not necessary to install a detoxifying apparatus on a processing apparatus that performs the modifying process. Thus, a configuration of the processing apparatus is simplified.

As described above, in accordance with the method for manufacturing a semiconductor device according to the first embodiment, it is possible to prevent the shape of the memory hole from becoming the bowing shape, and it is possible to form the memory hole with high processing accuracy.

### Second Embodiment

A method for manufacturing a semiconductor device according to a second embodiment is different from the method for manufacturing a semiconductor device according to the first embodiment in that a silylating agent is supplied to the recess after the first etching process and before the second etching process. Hereinafter, a part of contents overlapping the contents of the first embodiment will not be described.

The method for manufacturing a semiconductor device according to the second embodiment is a method for manufacturing the nonvolatile memory 100 illustrated in FIG. 1, similarly to the method for manufacturing a semiconductor device according to the first embodiment.

In the method for manufacturing a semiconductor device according to the second embodiment, after the first etching process and before the first modifying process, a first silylation process of supplying trimethylsilyl dimethylamine (TMSDMA) to the memory hole MH is performed. Trimethylsilyl dimethylamine is an example of a silylating agent.

The first silylation process is performed by using, for example, the RIE apparatus illustrated in FIG. 2. The first silylation process is performed, for example, in the same chamber 20 as the first etching process. For example, after the first etching process is performed, the first silylation process is continuously performed without releasing the silicon substrate 10 to the atmosphere.

The first silylation process is performed, for example, by supplying TMSDMA into the chamber 20 from the gas supply port 23 of the RIE apparatus. In the first silylation process, TMSDMA is supplied as a gas to the memory hole MH.

The protective film is formed on the sidewall of the memory hole MH by the first silylation process. The protective film contains carbon.

After the first silylation process, for example, the first modifying process is performed by using the microwave plasma apparatus illustrated in FIG. 3.

For example, after the second etching process and before the second modifying process, a second silylation process similar to the first silylation process is performed. For example, after the third etching process and before the third modifying process, a third silylation process similar to the first silylation process is performed.

The silylating agent is a chemical agent that realizes silylation. Silylation means that active hydrogen on the substance is substituted with a trisubstituted silyl group (—SiR₃). The silylating agent contains silicon (Si).

The silylating agent contains, for example, carbon and hydrogen. The silylating agent includes, for example, a methyl group, an alkyl group, or a phenyl group.

The silylating agent contains, for example, an amino group. The silylating agent has, for example, a structure of (R₃)—Si—N(R₂). The silylating agent is, for example, trimethylsilyl dimethylamine (TMSDMA), bis-tertiary butylaminosilane (BTBAS), bis(dimethylamino)dimethylsilane (BDMADMS), or phenyldimethylsilyldimethylamine.

The silylating agent contains, for example, a methoxy group. The silylating agent has, for example, a structure of R—Si—(O(Me))x. The silylating agent has, for example, a structure of CH₃—(CH₂)z-Si—(O-Me)₃. The silylating agent is, for example, trimethylmethoxysilane (TMSOME), dimethyldimethoxysilane (DMDMS), methyltrimethoxysilane (MTMS), or methoxydimethylphenylsilane.

Next, functions and effects of the method for manufacturing a semiconductor device according to the second embodiment will be described.

The bowing shape of the memory hole is caused by an increase in the hole diameter during etching for forming the memory hole. It is considered that a part of the protective film formed on the sidewall of the memory hole during the etching disappears as the cause of the increase in the hole diameter during the etching.

During the etching of the memory hole, substances derived from plasmised etching gas adhere to the sidewall, and a protective film is formed on the sidewall. The etching of the sidewall is suppressed by forming the protective film on the sidewall of the memory hole, and the increase in the hole diameter is suppressed. When the protective film on the sidewall of the memory hole disappears, the etching of the sidewall of the memory hole progresses, and the hole diameter of the memory hole increases.

The protective film formed on the sidewall of the memory hole is, for example, a fluorocarbon film containing carbon and fluorine.

A thickness of the protective film formed on the sidewall of the memory hole is determined by balance between the amount of substances adhering to the sidewall and the etching amount of substances adhering to the sidewall.

For example, on the sidewall of a shallow portion of the memory hole, the plasmised etching gas easily reaches, and the amount of substances adhering to the sidewall increases. On the other hand, in the shallow portion of the memory hole, the amount of obliquely incident ions is large, and a time to be exposed to etching is also long. Thus, the etching amount of substances adhering to the sidewall also increases. There is a concern that the etching amount exceeds the amount of substances adhering to the sidewall, the protective film on the sidewall disappears, and the hole diameter of the memory hole increases.

For example, in the sidewall of the deep portion of the memory hole, the plasmised etching gas hardly reaches, and the amount of substances adhering to the sidewall decreases. Thus, when the etching amount exceeds the amount of substances adhering to the sidewall, there is a concern that the protective film on the sidewall disappears and the hole diameter of the memory hole increases.

In the method for manufacturing a semiconductor device according to the second embodiment, when the memory hole MH is formed, the etching process of the stacked body 40 which is the layer to be processed and the process using the silylating agent are alternately performed. The protective film is formed on the sidewall of the memory hole by the process using the silylating agent. By the process using the silylation agent, a new protective film is also formed at a portion where the protective film formed during the etching disappears. Accordingly, it is considered that the shape of the memory hole can be prevented from becoming the bowing shape.

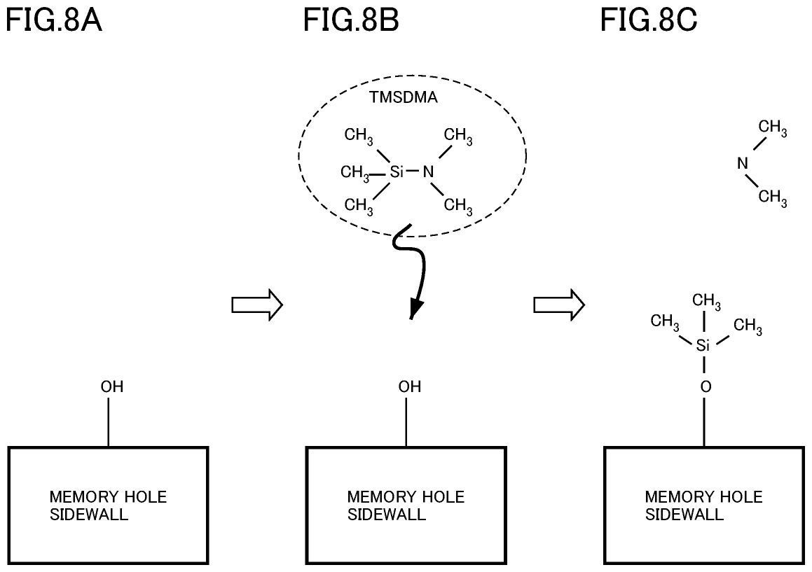

FIGS. 8A, 8B, and 8C are explanatory diagrams of functions of the method for manufacturing a semiconductor device according to the second embodiment.

As illustrated in FIG. 8A, a hydroxyl group (—OH) is present on the surfaces of the silicon oxide layer 40a and the silicon nitride layer 40b exposed on the sidewall of the memory hole MH. As illustrated in FIG. 8B, in the method for manufacturing a semiconductor device according to the second embodiment, TMSDMA as the silylation agent is supplied to the surface of the sidewall of the memory hole MH during the first silylation process, the second silylation process, and the third silylation process.

As illustrated in FIG. 8C, an Si—N bond of TMSDMA supplied to the surface of the sidewall of the memory hole MH is broken, and a trimethylsilyl group is bonded to the surface of the sidewall. The trimethylsilyl group is bonded to the surface of the sidewall of the memory hole MH by a silylation reaction.

The protective films formed by the first silylation process, the second silylation process, and the third silylation process are, for example, the trimethylsilyl group formed by the silylation reaction.

The silylation reaction is highly reactive and easily occurs even at a low temperature. For the silylation reaction, it is not necessary to plasmise the material to form ions and radicals.

Since the silylation reaction has high reactivity, the protective film is easily formed even in a deep portion of the memory hole MH. When the surface of the sidewall is completely covered with the trimethylsilyl group, the silylation reaction is ended. Accordingly, the formation of the protective film is a self-limiting process. Thus, it is considered that the protective films formed on the sidewall by the first silylation process, the second silylation process, and the third silylation process have a uniform thickness.

It is considered that the etching of the sidewall is suppressed by forming the protective film by the first silylation process, the second silylation process, and the third silylation process and the shape of the memory hole MH can be prevented from becoming the bowing shape.

It is preferable that the first to fourth etching gases contain oxygen. It is preferable that the first to fourth etching gases contain an oxygen gas.

When the oxygen or the oxygen gas is contained in the first to fourth etching gases, the surface of the silicon nitride layer 40b on the sidewall of the memory hole MH is oxidized. Thus, a surface state of the silicon oxide layer 40a exposed to the sidewall is similar to a surface state of the silicon nitride layer 40b. Thus, the silylation reaction on the surface of the silicon oxide layer 40a and the silylation reaction on the surface of the silicon nitride layer 40b progress similarly. Accordingly, the protective film formed by the silylation reaction becomes a uniform film. Thus, the silicon nitride layer 40b on the sidewall is prevented from being selectively etched with respect to the silicon oxide layer 40a on the sidewall.

It is preferable that the first to fourth etching gases contain hydrogen. When the first to fourth etching gases contain hydrogen, an etching rate of the silicon nitride layer 40b increases. Thus, etching times of the first to fourth etching processes can be shortened.

### MODIFICATION EXAMPLE

A modification example of the method for manufacturing a semiconductor device according to the second embodiment is different from the method for manufacturing a semiconductor device according to the second embodiment in that the first silylation process is performed after the first modifying process and before the second etching process.

The first silylation process is performed by using, for example, the microwave plasma apparatus illustrated in FIG. 3. The first silylation process is performed, for example, in the same chamber 25 as the first modifying process. For example, after the first modifying process is performed, the first silylation process is continuously performed without releasing the silicon substrate 10 to the atmosphere.

The first silylation process is performed, for example, by supplying TMSDMA into the chamber 25 from the gas supply port 28 of the microwave plasma apparatus. The protective film is formed on the sidewall of the memory hole MH by the first silylation process.

After the first silylation process is performed, for example, the second etching process is performed by using the RIE apparatus illustrated in FIG. 2.

For example, after the second modifying process and before the third etching process, the second silylation process similar to the first silylation process is performed. For example, after the third modifying process and before the fourth etching process, the third silylation process similar to the first silylation process is performed.

As described above, in accordance with the method for manufacturing a semiconductor device according to the second embodiment, and the modification example thereof, it is possible to suppress the shape of the memory hole from becoming the bowing shape, and it is possible to form the memory hole with high processing accuracy. In accordance with the method for manufacturing a semiconductor device according to the second embodiment and the modification example thereof, the memory hole can be formed with higher processing accuracy than in the method for manufacturing a semiconductor device according to the first embodiment by performing the silylation process.

### Third Embodiment

A method for manufacturing a semiconductor device according to a third embodiment is different from the method for manufacturing a semiconductor device according to the first embodiment in that the first etching process and the first process are performed in the same chamber. Hereinafter, a part of contents overlapping the contents of the first embodiment will not be described.

The method for manufacturing a semiconductor device according to the third embodiment is a method for manufacturing the nonvolatile memory 100 illustrated in FIG. 1, similarly to the method for manufacturing a semiconductor device according to the first embodiment.

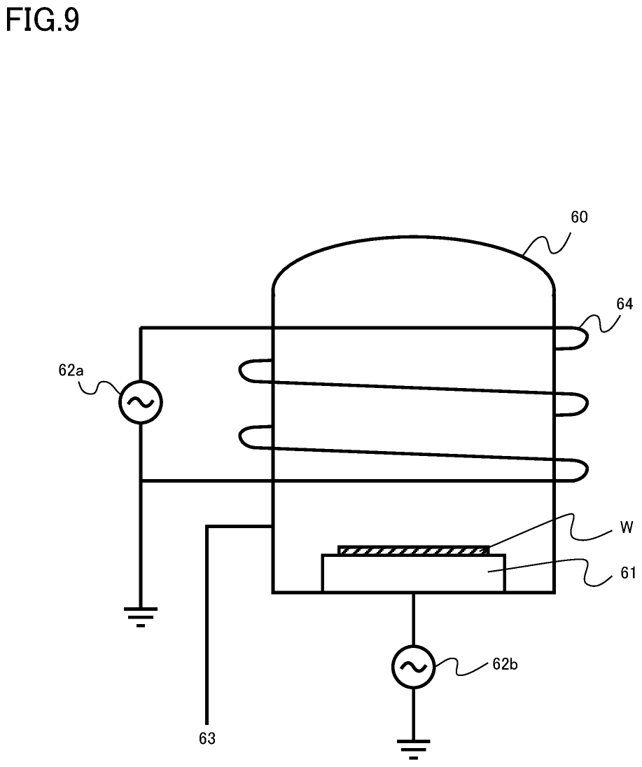

FIG. 9 is a schematic diagram of an example of a reactive ion etching apparatus used in the method for manufacturing a semiconductor device according to the third embodiment. The reactive ion etching apparatus (RIE apparatus) generates plasma by using an inductively coupled plasma method.

The RIE apparatus includes a chamber 60, a holder 61, a source power supply 62a, a bias power supply 62b, a gas supply port 63, and an induction coil 64.

The holder 61 is provided in the chamber 60. The holder 61 mounts the semiconductor substrate W, for example. The holder 61 has, for example, an electrostatic chuck on an upper portion.

The source power supply 62a has a function of applying a high-frequency power to the induction coil 64. When the high-frequency power is applied to the induction coil 64, plasma is generated in the chamber 60. The high-frequency power to be applied to the induction coil 64 is, for example, equal to or more than 100 W and equal to or less than 1000 W.

The bias power supply 62b has a function of applying a high-frequency power to the holder 61. Kinetic energy of ions colliding with the semiconductor substrate W is controlled by applying high-frequency power to the holder 61. The high-frequency power to be applied to the holder 61 is, for example, equal to or more than 100 W and equal to or less than 500 W.

The semiconductor substrate W is anisotropically etched by using the plasma generated in the chamber 60.

In the method for manufacturing a semiconductor device according to the third embodiment, the RIE apparatus illustrated in FIG. 9 is used in the first etching process.

In the chamber 60 of the RIE apparatus, the first etching process is performed by using the mask layer 42 as a mask. The memory hole MH is formed on the surface of the stacked body 40 by the first etching process.

During the first etching process, for example, the first etching gas is supplied from the gas supply port 63 into the chamber 60.

A temperature of the silicon substrate 10 during the first etching process is, for example, equal to or less than 20° C. The first etching process is performed on the silicon substrate 10 in a state of, for example, 20° C. or lower.

During the first etching process, a first protective film 44a is formed on a surface of the memory hole MH. The first protective film 44a is formed, for example, on a sidewall of the memory hole MH.

After the first etching process, the first modifying process of supplying the hydrogen radicals to the memory holes MH is performed in the chamber 60 of the RIE apparatus. After the first etching process is performed, the first modifying process is continuously performed without releasing the silicon substrate 10 into the atmosphere.

During the first modifying process, the first modifying gas is supplied from the gas supply port 63. The first modifying gas is a gas containing hydrogen (H).

The first modifying process is performed in a state where the temperature of the silicon substrate 10 is equal to or more than 200° C. and equal to or less than 350° C. The temperature of the silicon substrate 10 during the first modifying process is higher than, for example, the temperature of the silicon substrate 10 during the first etching process.

For example, a temperature of the holder 61 is increased by decreasing a pressure of a refrigerant flowing through a flow path (not illustrated in FIG. 9), and the temperature of the silicon substrate 10 is increased.

The high-frequency power to be applied to the holder 26 by the bias power supply 62b during the first modifying process is lower than the high-frequency power to be applied to the holder 26 by the bias power supply 62b during the first etching process, for example. The high-frequency power to be applied to the silicon substrate 10 during the first modifying process is lower than the high-frequency power to be applied to the silicon substrate 10 during the first etching process.

After the first modifying process, for example, the second etching process similar to the first etching process is performed in the chamber 60 of the RIE apparatus.

After the second etching process, for example, the second modifying process similar to the first modifying process is performed in the chamber 60 of the RIE apparatus.

After the second modifying process, for example, the third etching process similar to the second etching process is performed in the chamber 60 of the RIE apparatus.

After the third etching process, for example, the third modifying process similar to the first modifying process is performed in the chamber 60 of the RIE apparatus.

After the third modifying process, for example, the fourth etching process similar to the first etching process is performed in the chamber 60 of the RIE apparatus.

In the method for manufacturing a semiconductor device according to the third embodiment, all of the first etching process, the first modifying process, the second etching process, the second modifying process, the third etching process, the third modifying process, and the fourth etching process are performed in the chamber 60 of the same RIE apparatus. Accordingly, the throughput of the RIE for forming the memory hole MH is improved.

As described above, in accordance with the method for manufacturing a semiconductor device according to the third embodiment, it is possible to prevent the shape of the memory hole from becoming the bowing shape, and it is possible to form the memory hole with high processing accuracy. The throughput of the RIE for forming the memory hole MH is further improved than the throughput in the method for manufacturing a semiconductor device according to the first embodiment.

In the first to third embodiments, although the case where the etching process is performed four times and the modifying process of the protective film is performed three times during each etching has been described as an example, the number of times of the etching process is not limited to four and the number of times of the modifying process is not limited to three. The number of times of the etching process may be any number as long as the number of times of the etching process is two or more and the number of times of the modifying process is one or more.

In the first to third embodiments, although the case where the semiconductor device is the nonvolatile memory has been described as an example, the semiconductor device is not limited to the nonvolatile memory.

In the first embodiment, although the case where the first layer of the layer to be processed is the silicon oxide layer and the second layer is the silicon nitride layer has been described as an example, the first layer and the second layer are not limited to the combination of the silicon oxide layer and the silicon nitride layer as long as the first layer and the second layer are different layers. For example, a combination of an insulating layer and a semiconductor layer, or a combination of an insulating layer and a metal layer may be used.

In the first embodiment, although the case where the layer to be processed includes the stacked structure of the first layer and the second layer has been described as an example, the layer to be processed may have a single layer structure.

In the first to third embodiments, although the case where the memory hole MH is formed in the layer to be processed by etching has been described as an example, the pattern formed in the layer to be processed is not limited to the hole pattern. The pattern formed in the layer to be processed may be, for example, a groove pattern.

While certain embodiments have been described, these embodiments have been presented by way of example only, and are not intended to limit the scope of the inventions. Indeed, the method for manufacturing a semiconductor device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A method for manufacturing a semiconductor device, comprising:
performing a first etching process forming a recess in a layer to be processed formed on a substrate, the recess formed by reactive ion etching using a first gas;
performing a first process after the first etching process, the first process supplying hydrogen radicals to the recess by using a second gas containing hydrogen in a state where a temperature of the substrate is equal to or more than 200° C. and equal to or less than 350° C.; and
performing a second etching process after the first process, the second etching process etching a bottom surface of the recess by reactive ion etching using a third gas.

2. The method for manufacturing a semiconductor device according to claim 1, wherein the first gas contains carbon and fluorine.

3. The method for manufacturing a semiconductor device according to claim 1, wherein a first film is formed in the first etching process on a surface of the recess by the reactive ion etching using the first gas.

4. The method for manufacturing a semiconductor device according to claim 3, wherein the first film contains carbon and fluorine.

5. The method for manufacturing a semiconductor device according to claim 3, wherein the first film is reduced in the first process.

6. The method for manufacturing a semiconductor device according to claim 3, wherein a fluorine concentration of the first film decreases in the first process.

7. The method for manufacturing a semiconductor device according to claim 1, wherein the second gas contains a hydrogen gas.

8. The method for manufacturing a semiconductor device according to claim 7, wherein the second gas further contains a nitrogen gas, a volume ratio of the hydrogen gas in the second gas is equal to or less than 10%, and a volume ratio of the nitrogen gas is equal to or more than 80%.

9. The method for manufacturing a semiconductor device according to claim 1 further comprising:
forming a mask layer having a pattern before the performing the first etching process, the mask layer formed on the layer to be processed,
wherein the recess is formed with the mask layer as a mask in the first etching process.

10. The method for manufacturing a semiconductor device according to claim 9, wherein the mask layer contains carbon.

11. The method for manufacturing a semiconductor device according to claim 1, wherein a temperature of the substrate during the first process is higher than a temperature of the substrate during the first etching process.

12. The method for manufacturing a semiconductor device according to claim 1, wherein a high-frequency power applied to the substrate during the first process is lower than a high-frequency power applied to the substrate during the first etching process.

13. The method for manufacturing a semiconductor device according to claim 1, wherein the hydrogen radicals are generated from the second gas by using an inductively coupled plasma method, a microwave plasma method, an electron cyclotron resonance method, a helicon wave method, or a hot filament method.

14. The method for manufacturing a semiconductor device according to claim 1, wherein the layer to be processed contains silicon.

15. The method for manufacturing a semiconductor device according to claim 1, wherein the layer to be processed has a structure in which a first layer and a second layer different from the first layer are alternately stacked.

16. The method for manufacturing a semiconductor device according to claim 15, wherein the first layer is a silicon oxide layer, and the second layer is a silicon nitride layer.

17. The method for manufacturing a semiconductor device according to claim 1, wherein the first etching process is performed in a first chamber, and the first process is performed in a second chamber different from the first chamber.

18. The method for manufacturing a semiconductor device according to claim 1 further comprising:
supplying a silylating agent to the recess after the performing the first etching process and before the performing the second etching process.

19. The method for manufacturing a semiconductor device according to claim 18, wherein the silylating agent contains carbon and hydrogen.

20. The method for manufacturing a semiconductor device according to claim 1, further comprising:
performing a second process after the second etching process, the second process supplying hydrogen radicals to the recess by using a fourth gas containing hydrogen in a state where a temperature of the substrate is equal to or more than 200° C. and equal to or less than 350° C.; and
performing a third etching process after the second process, the third etching process etching the bottom surface of the recess by reactive ion etching using a fifth gas.
